(19) United States
(12) Patent Application Publication
(10) Pub. No.: US 2010/0169037 A1
(43) Pub. Date: Jul. 1, 2010

(54) FLASH MEMORY THRESHOLD VOLTAGE CHARACTERIZATION

(75) Inventors: Harland Glenn Hopkins, Missouri City, TX (US); David J. Livingston, Richmond, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 12/345,522

(22) Filed: Dec. 29, 2008

(51) Int. Cl. G01R 27/28

(52) U.S. Cl. 702/117

(57) ABSTRACT

In an embodiment, the invention provides a method for characterizing a threshold voltage of a flash memory cell. The method comprises generating a pulse train signal on flash memory IC, applying the pulse train signal to an external low-pass filter, and applying an output of the low-pass filter to the input of an external gain stage. An analog signal from the output of the gain stage is directed to a control gate of the flash memory cell. An electrical parameter of the flash memory cell is measured by an external tester.

### BACKGROUND

External reference components are often used to calibrate the performance of an individual circuit on an integrated circuit (IC). These components include but are not limited to passive components such as resistors, capacitors, and inductors. These components also include but are not limited to active components such as op-amps, voltage regulators, current regulators, and precession voltage references. The number of external reference components used to characterize individual circuits on an IC often adds to the cost of producing ICs, components, electrical boards, and computer systems. One method used to reduce the cost of producing ICs is to reduce the number of external reference components used to calibrate or test ICs.

### BRIEF DESCRIPTION OF THE DRAWINGS

FIG. 1 is a schematic diagram of a side cutaway view of an embodiment of a flash memory cell.

FIG. 2 is a block diagram of an exemplary embodiment of an IC, a tester, and an analog voltage reference.

FIG. 3A is a schematic drawing of a first exemplary embodiment of a low-pass filter.

FIG. 3B is a schematic drawing of a second exemplary embodiment of a low-pass filter.

FIG. 4 is a schematic drawing of an embodiment of a gain stage.

FIG. 5 is a block diagram of an exemplary embodiment of an IC, a tester, and analog voltage references.

### DETAILED DESCRIPTION

In a first embodiment of the invention, an analog voltage reference is used to generate an analog signal for measuring the V_{T} (threshold voltage) of a flash memory cell. The analog voltage reference in this example replaces more complex and costly precession voltage references. As will be described in more detail, the analog voltage reference receives a PWM (Pulse Width Modulated) signal from a pulse train generator on a flash memory IC. The pulse train generator is controlled by a CPU (Central Processing Unit). After receiving the PWM signal, the analog voltage reference generates an analog voltage that is applied to test logic on the flash memory IC. Test logic on the flash memory IC applies the analog voltage generated by the analog voltage reference to a gate of a flash memory cell. A digital output signal based on either a current or a voltage generated by the flash memory cell is sent to an external tester. The digital output signal, in this example, is controlled by the CPU.

Flash memory stores information in an array of memory cells made from floating-gate transistors. In traditional single-level cell (SLC) devices, each cell stores only one bit of information. Some flash memory, known as multi-level cell (MLC) devices, can store more than one bit per cell by choosing between multiple levels of electrical charge to apply to the floating gates of its cells.

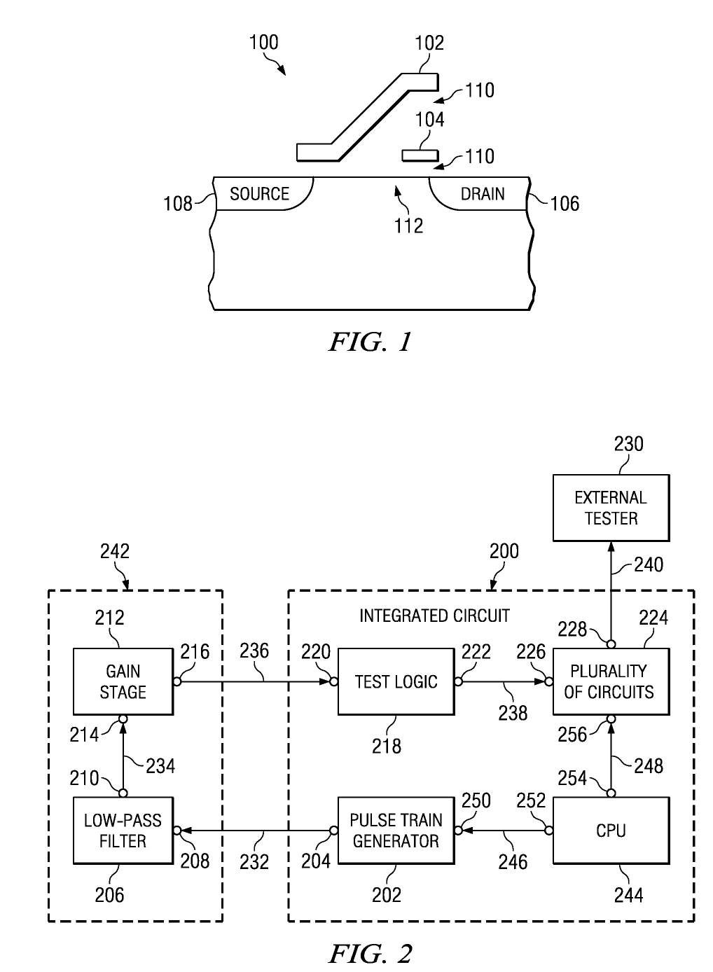

FIG. 1 is a schematic diagram of a side cutaway view of an embodiment of a flash memory cell. In NOR-gate flash memory, each flash memory cell (100) resembles a standard MOSFET (metal-oxide semiconductor field-effect transistor) except the transistor has two gates instead of one. On top is the control gate (102), as in other MOS (metal-oxide semiconductor) transistors, however below the control gate (102) there is a floating gate (104) insulated by an oxide layer (110). The floating gate (104) is interposed between the control gate (102) and the MOSFET channel (112).

Because the floating gate (104) is electrically isolated by the oxide layer (110), any electrons placed on the floating gate (104) are trapped on the floating gate (104). Under normal conditions, the floating gate (104) will not discharge for many years. When the floating gate (104) retains charge, it screens (partially cancels) the electric field from the control gate (102), which modifies the V_{T} of the cell. During read-out, a voltage is applied to the control gate (102), and the MOSFET channel (112) will become conducting or remain insulating, depending on the V_{T} of the cell, which is in turn controlled by charge on the floating gate (104).

If the MOSFET channel (112) becomes conducting, current flows through the MOSFET channel (112) from the drain (106) to the source (108). The absence or the presence of current flowing through the MOSFET channel (112) may be sensed forming a binary code wherein stored data may be reproduced.

In a multi-level cell device, which stores more than one bit per cell, the amount of current flow is sensed (rather than simply its presence or absence), in order to determine more precisely the level of charge on the floating gate (104).

FIG. 2 is a block diagram of an exemplary embodiment of an IC, a tester, and an analog voltage reference. A pulse train generator (202), internal to an integrated circuit (200) generates a pulse train signal (232). A CPU (244) controls the pulse train signal (232) through a control signal 246. The pulse train signal (232) generated may, for example, be a PWM (Pulse lo Width Modulated) signal. The pulse train signal (232) is connected to the input (208) of a low-pass filter (206). The low-pass filter (206) is external to the IC (200). The low-pass filter (206) removes high-frequency components in the pulse train signal (232). A low-pass filter (206) may be created in a number of ways as shown below.

In FIG. 2, the low-pass filter (206) is connected to a gain stage (212). The gain stage (212) is external to the IC (200). The gain stage (212) increases the voltage (234) received from the output (210) of the low-pass filter (206). The gain stage (212) creates an analog signal (236) at its output (216). The gain stage (212) may, for example, be created using an op-amp and two resistors as shown below. The combination of the low-pass filter (206) and the gain stage (21) creates an analog voltage reference (242).

The analog signal (236) is connected to an input (220) of test logic (218). The test logic (218) is internal to the IC (200). An output (222) of the test logic connects the analog signal (236) to an input (226) of at least one circuit in the plurality of circuits (224). The plurality of circuits may, for example, be flash memory cells of a flash memory IC. In addition, the plurality of circuits may, for example, be ADCs (Analog-to-Digital Converters). These two examples are discussed in more detail below.

An output (228) from the plurality of circuits (224) is connected to an external tester (230). The external tester (230), for example, receives a digital output signal (240) based on either a current or a voltage generated by a flash memory cell. The digital output signal (240) is controlled by the CPU (244) through signal 248. The external tester (230) may also receive a digital output signal (240) based on either a current or a voltage generated by an ADC.

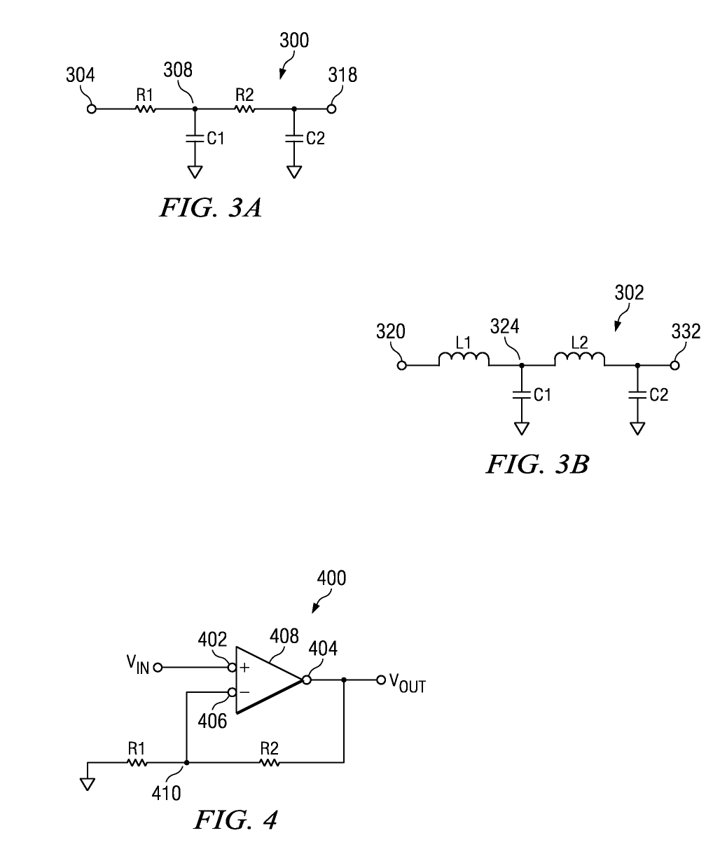

FIG. 3A shows a schematic drawing of a first exemplary embodiment of a low-pass filter (300). The input (304) of the low-pass filter (300) is connected to a first node of resistor R1. A second node (308) of resistor R1 is connected to a first node of capacitor C1 and a first node of resistor R2. A second node of capacitor C1 is connected to ground. A second node of resistor R2 is connected to a first node of capacitor C2 and the output (318) of the low-pass filter (300). A second node of capacitor C2 is connected to ground.

FIG. 3B shows a schematic drawing of a second exemplary embodiment of a low-pass filter (302). The input (320) of the low-pass filter (302) is connected to a first node of inductor L1. A second node (324) of inductor L1 is connected to a first node of capacitor C1 and a first node of inductor L2. A second node of capacitor C1 is connected to ground. A second node of inductor L2 is connected to a first node of capacitor C2 and the output (332) of the low pass filter (302). A second node of capacitor C2 is connected to ground.

Other types of low-pass filters may be used such as first order, second order, third order, and fourth order low-pass filters.

FIG. 4 shows a schematic drawing of a gain stage (400). The gain stage (400) in FIG. 4 includes an op-amp (408) and two resistors, R1 and R2. The op-amp (408) includes a positive input (402), a negative input (406), and an output (404). A first node of the first resistor R1, the negative input (406) of the op-amp (408), and a first node of the second resistor R2 are connected to node 410. A second node of the first resistor R1 is connected to ground. The second node of the second resistor R2 and the output (404) of the op-amp (408) are connected at V_{OUT}. The input (V_{IN}) of the gain stage (400) is connected to the positive input (402) of the op-amp (408). The gain (V_{OUT}V_{IN}) of the gain stage (400) is determined as follows:

V_{OUT}/V_{IN}=1+(R2/R1)

In a first embodiment of the invention, the integrated circuit (200) is a flash memory integrated circuit and the plurality of circuits (224) contains at least flash memory cells. The pulse train generator (202), located on the flash memory IC (200), generates a pulse train signal (232). The pulse train signal (232) is controlled by a signal (246) from a CPU (244). In this exemplary embodiment, the pulse train signal (232) is a PWM signal. The duty cycle of the PWM signal may be varied in order to create a specific analog value at the output (210) of the low-pass filter (206). The amplitude of the PWM signal may also be varied in order to create a specific analog value at the output (210) of the low-pass filter (206). The control of the PWM signal is not limited to controlling the duty cycle or the amplitude of the PWM signal.

In the first embodiment of the invention, the output (210) of the external low-pass filter (206) is connected to the input (214) of the external gain stage (212). The output voltage (216) is determined by the gain of the external gain stage (212). The analog signal (236) created by the external gain stage (212) is connected to the input (220) of the test logic (218). The test logic (218) located on the flash memory IC (200) applies the analog signal lo (236) to a gate (102) of a flash memory cell (100).

An output (228) from the plurality of circuits (224) is connected to an external tester (230). The external tester (230), for example, receives a digital output signal (240) based on either current or voltage generated by one or more flash memory cells. The digital output signal (240) is controlled by a signal 248 from the CPU (244).

In a second embodiment of the invention, the plurality of circuits (224) contains at least ADCs. The pulse train generator (202), located on the IC (200), generates a pulse train signal (232). In this exemplary embodiment, the pulse train signal (232) is a PWM signal. The pulse train signal (232) is controlled by a signal (246) from a CPU (244). The duty cycle of the PWM signal may be varied in order to create a specific analog value at the output (210) of the low-pass filter (206). The amplitude of the PWM signal may also be varied in order to create a specific analog value at the output (210) of the low-pass filter (206). The control of the PWM signal is not limited to controlling the duty cycle or the amplitude of the PWM signal.

In the second embodiment of the invention, the output (210) of the external low-pass filter (206) is connected to the input (214) of the external gain stage (212). The output voltage (216) is determined by the gain of the external gain stage (212). The analog signal (236) created by the external gain stage (212) is connected to the input (220) of the test logic (218). The test logic (218) located on the IC (200) applies the analog signal (236) to an input of an ADC.

An output (228) from the plurality of circuits (224) is connected to an external tester (230). The external tester (230), for example, receives a 1o digital output signal (240) based on either current or voltage generated by one or more ADCs. The digital output signal (240) is controlled by a signal 248 from the CPU (244).

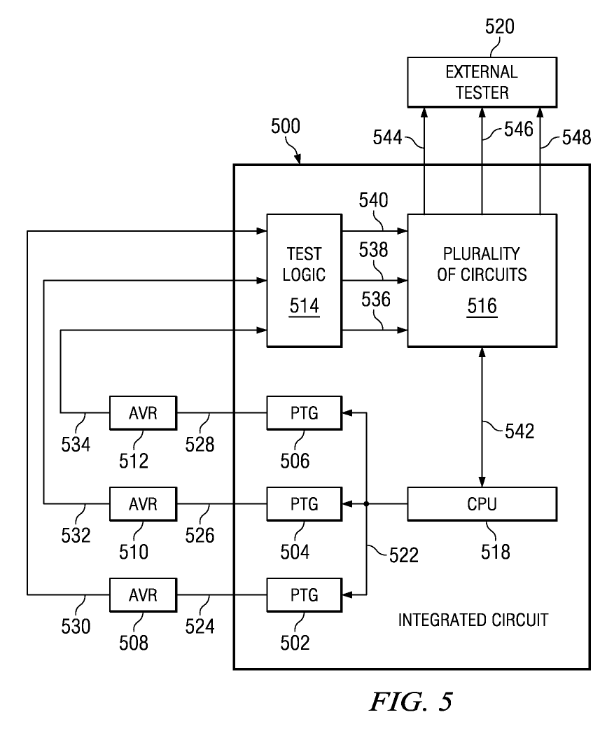

FIG. 5 is a block diagram of an exemplary embodiment of an IC, a tester, and analog voltage references. In a third embodiment of the invention, three pulse train generator (502, 504, and 506) create three impulse train signals (524, 526, and 528). In this exemplary embodiment, the pulse train signals (524, 526, and 528) are PWM signals. The pulse train signals (524, 526, and 528) are controlled by a signal (522) from a CPU (518). The duty cycle of the PWM signals may be varied in order to create a specific analog value at the outputs of the low-pass filters. The amplitude of the PWM signals may also be varied in order to create specific analog values at outputs of low-pass filters. The control of the PWM signals is not limited to controlling the duty cycle or the amplitude of the PWM signals.

In the third embodiment of the invention, the pulse train signals (524, 526, and 528) are connected to analog voltage references (508, 510, and 512) respectively. These analog voltage references (508, 510, and 512) may be created using a low-pass filter (206) and a gain stage (212) as shown in FIG. 2. The analog signals (530, 532, and 534) created by the analog voltages references (508, 510, and 512) are connected to test logic (514). The test logic (514) located on the IC (200) applies the analog signals (530, 532, and 534) to inputs of flash memory cells.

Digital outputs signals (544, 546, and 548) from the plurality of circuits (516) are connected to an external tester (520). The external tester (520), for example, receives digital output signals (544, 546, and 548) based on either current or voltage generated by flash memory cells. The digital output signals (544, 546, and 548) are controlled by a signal 542 from the CPU (518). In this example, three flash memory cells may be tested concurrently reducing the time required to test all the flash memory cells in the flash memory IC (500). In this example where three pulse train generators (502, 504, and 506) and three analog voltage references (508, 510, and 512) are is described for illustrative purposes. It is understood that more flash memory cells may be tested concurrently by adding more internal pulse train generators and more external analog voltage generators.

In addition to testing more flash memory cells concurrently on an individual flash memory IC as in FIG. 5, one or more individual flash memory ICs may be tested concurrently (not shown.) In this case, each individual flash memory IC has at least one pulse train generator internal to the flash memory IC and at least one analog voltage reference external to the flash memory IC. One or more digital outputs signals from the individual flash memory ICs are connected to an external tester. As result of this configuration, the time required to test flash memory ICs is reduced. Other individual ICs may also be tested concurrently.

The foregoing description has been presented for purposes of illustration and description. It is not intended to be exhaustive or to limit the invention to the precise form disclosed, and other modifications and variations may be possible in light of the above teachings. The exemplary embodiments were chosen and described in order to best explain the applicable principles and their practical application to thereby enable others skilled in the art to best utilize various embodiments and various modifications as are suited to the particular use contemplated. It is intended that the appended claims be construed to include other alternative embodiments except insofar as limited by the prior art.

What is claimed is:

1. A system for testing integrated circuits comprising:
a pulse train generator located on an integrated circuit, the pulse train generator having an input and an output;
a CPU located on the integrated circuit, the CPU having an output and an input/output (I/O);
a plurality of circuits located on the integrated circuit, the plurality of circuits having an input, an output and an I/O;
test logic located on the integrated circuit, the test logic having an input and an output;
a low-pass filter located external to the integrated circuit, the low-pass filter having an input and an output;
a gain stage located external to the integrated circuit, the gain stage having an input and an output;
an external tester located external to the integrated, the external tester having an input;
wherein the output of the pulse train generator creates a pulse train signal;
wherein the input of the pulse train generator is connected to the output of the CPU;
wherein the pulse train signal is connected to the input of the low-pass filter;
wherein the output of the low-pass filter is connected to an input of the gain stage;
wherein the output of the gain stage generates an analog signal;
wherein the analog signal is connected to the input of the test logic;
wherein the output of the test logic is connected to the plurality of circuits;
wherein the output of the plurality of circuits is connected to the input of the external tester;
wherein the I/O of the plurality of circuits is connected to the I/O of the CPU;
wherein at least one characteristic of at least one circuit of the plurality of circuits is sent to the input of the external tester.

2. The system as in claim 1 wherein the low-pass filter comprises:
a first resistor having a first node and a second node;
a first capacitor having a first node and a second node;
a second resistor having a first node and a second node;
a second capacitor having a first node and a second node;
wherein the input of the low-pass filter is connected to the first node of the first resistor;
wherein the second node of the first resistor is connected to the first node of the first capacitor and the first node of the second resistor;
wherein the second node of the first capacitor is connected to ground;
wherein the second node of the second resistor is connected to the first node of the second capacitor and the output of the low-pass filter;
wherein the second node of the second capacitor is connected to ground.

3. The system as in claim 1 wherein the low-pass filter comprises:
a first inductor having a first node and a second node;
a first capacitor having a first node and a second node;
a second inductor having a first node and a second node;
a second capacitor having a first node and a second node;
wherein the input of the low-pass filter is connected to the first node of the first inductor;
wherein the second node of the first inductor is connected to the first node of the first capacitor and the first node of the second inductor;
wherein the second node of the first capacitor is connected to ground;
wherein the second node of the second inductor is connected to the first node of the second capacitor and the output of the low-pass filter;
wherein the second node of the second capacitor is connected to ground.

4. The system as in claim 1 wherein the low-pass filter is selected from a group consisting of a first order low-pass filter, a second order low-pass filter, a third order low-pass filter and a fourth order low pass filter.

5. The system as in claim 1 wherein the gain stage comprises:
an op-amp having a first input, a second input, and an output;
a first resistor having a first node and a second node;
a second resistor having a first node and a second node;
wherein the output of the op-amp is connected to the first node of the second resistor and the output of the gain stage;
wherein the second node of the second resistor is connected to the first node of the first resistor and the second input of the op-amp;
wherein the second node of the second resistor is connected to ground;
wherein the first input of the op-amp is connected to the input of the gain stage.

6. The system as in claim 1 wherein the plurality of circuits comprises flash memory cells.

7. The system as in claim 6 wherein the at least one characteristic of at least one circuit of the flash memory cells is the threshold voltage (V_{T}) of a flash memory cell.

8. The system as in claim 1 wherein the plurality of circuits comprises analog-to-digital converters (ADCs).

9. A method for characterizing the threshold voltage (V_{T}) of a flash memory cell comprising:
generating a pulse train signal on a flash memory integrated circuit;
applying the pulse train signal to an input of an external low-pass filter;
applying an output of the external low-pass filter to an input of an external gain stage;
directing an analog signal from the external gain stage to a control gate of the flash memory cell;
measuring an electrical parameter of the flash memory cell;
sending the measured electrical parameter of the flash memory cell to an external tester.

10. The method of claim 9 wherein the electrical parameter measured is a voltage from the flash memory cell.

11. The method of claim 9 wherein the electrical parameter measured is the presence or the absence of current drawn through the flash memory cell.

12. The method of claim 9 wherein the low-pass filter is selected from a group consisting of a first order low-pass filter, a second order low-pass filter, a third order low-pass filter and a fourth order low pass filter.

13. The method of claim 9 wherein the gain stage comprises:
an op-amp having a first input, a second input, and an output;
a first resistor having a first node and a second node;
a second resistor having a first node and a second node;
wherein the output of the op-amp is connected to the first node of the second resistor and the output of the gain stage;
wherein the second node of the second resistor is connected to the first node of the first resistor and the second input of the op-amp;
wherein the second node of the second resistor is connected to ground;
wherein the first input of the op-amp is connected to the input of the gain stage.

14. A system for testing integrated circuits comprising:
a means for generating a pulse train signal located on an integrated circuit, the means for generating a pulse train signal having an output;
a plurality of circuits located on the integrated circuit, each circuit of the plurality of circuits having an input and an output;
a means for controlling a signal located on the integrated circuit;
an external means for removing high frequency components from a pulse train signal having an input and an output;
a means for increasing the voltage of a signal located external to the integrated circuit, the means for increasing the voltage of a signal having an input and an output;
wherein the means for generating a pulse train signal creates a pulse train signal;
wherein the pulse train signal is connected to the input of the external means for removing high frequency components;
wherein the output of the external means for removing high frequency components is connected to an input of the means for increasing the voltage of a signal;
wherein the output of the means for increasing the voltage of a signal generates an analog signal;
wherein the analog signal is directed to the input of at least one circuit of the plurality of circuits;
wherein the output of the at least one circuit of the plurality of circuits is used to characterize the at least one circuit of the plurality of circuits.

15. The system as in claim 14 wherein the plurality of circuits comprises flash memory cells.

16. The system as in claim 15 wherein an output of at least one flash memory cell is used to characterize a V_{T} of the at least one flash memory cell.

17. The system as in claim 14 wherein the plurality of circuits comprises analog-to-digital converters (ADCs).
